(19) United States
(12) Patent Application Publication
(10) Pub. No.: US 2009/0258505 A1
(43) Pub. Date: Oct. 15, 2009

(54) SEMICONDUCTOR DEVICE MANUFACTURING METHOD

(75) Inventor: Masashi Takahashi, Chiba (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/489,814

(22) Filed: Jun. 23, 2009

Related U.S. Application Data
(62) Division of application No. 11/229,686, filed on Sep. 20, 2005.

(30) Foreign Application Priority Data
Oct. 7, 2004 (JP) 2004294982

(51) Int. Cl. H01L 21/316; H01L 21/318

(52) U.S. Cl. 438/762; 257/E21.283; 257/E21.293

(57) ABSTRACT

A manufacturing method for semiconductor devices having MOSFET gate insulation films The method includes forming a silicon oxide film, forming a silicon nitride film, nitriding the silicon nitride film, and first and second heat treatments.

### CROSS-REFERENCE TO RELATED APPLICATION

This is a division application of application Ser. No. 11/229,686, filed on Sep. 20, 2005, which is hereby incorporated by reference in its entirety for all purposes.

This application claims priority under 35 USC 119 from Japanese Patent Application No. 2004-294982, the disclosures of which is incorporated by reference herein.

### BACKGROUND OF THE INVENTION

1. Field of the Invention

The present invention relates to a manufacturing method for semiconductor devices such as MOSFETs, and more particularly to a manufacturing method for semiconductor devices employing improved gate insulation film formation.

2. Description of the Related Art

The gate insulation films of MOSFETs have become thinner as semiconductor elements and devices become ever more microscopic. A silicon oxynitride film in which nitrogen has been introduced to control diffusion of boron in the silicon substrate is used in gate insulation films of surface channel type PMOS-FETs having boron-diffused gate electrodes. This silicon oxynitride film is formed primarily by nitriding a silicon oxide film with heat treatment in an atmosphere of N₂O, NO, or NH₃.

However, nitrogen in the silicon oxynitride film is not evenly distributed in the gate insulation film and the silicon substrate. This deteriorates the device characteristics. In particular, as the gate insulation film becomes thinner, an increasing amount of nitrogen is distributed unevenly in the interface of the gate insulation film and the silicon substrate. This greatly deteriorates the device characteristics, and cancels out the benefits of reduced thickness of the gate insulation film. An example of such MOSFET gate insulation film is disclosed in Japanese Patent Kokai (Application Laid-open) No. 2002-222941.

### SUMMARY OF THE INVENTION

One object of the present invention is to provide a novel manufacturing method for semiconductor devices to solve the problem of uneven distribution of nitrogen in the interface between the gate insulation film and the silicon substrate, while permitting reduced thickness of the silicon oxynitride film. The silicon oxynitride film is a MOSFET gate insulation film. The uneven distribution of nitrogen causes major deterioration of the semiconductor device characteristics

According to a first aspect of the present invention, there is provided a method that includes forming a silicon oxide film on a semiconductor substrate, forming a silicon nitride film on the silicon oxide film, nitriding the silicon nitride film, and performing a heat treatment after nitriding the silicon nitride film.

According to a second aspect of the present invention, there is provided a method that includes forming a silicon oxide film on a semiconductor substrate, forming a silicon nitride film on the silicon oxide film, performing a heat treatment process following formation of the silicon nitride film, nitriding the silicon nitride film following the heat treatment process, and performing another heat treatment process following nitriding of the silicon nitride film.

Preferably, the silicon nitride film is formed with the ALD (Atomic Layer Deposit) method.

Preferably, the nitriding is radical nitriding employing nitrogen plasma.

The silicon oxynitride film (i.e., MOSFET gate insulation film) is very thin, but entry of nitrogen into the interface between the gate insulation film and the silicon substrate is prevented. Thus, deterioration of a semiconductor device characteristics is prevented.

### BRIEF DESCRIPTION OF THE DRAWINGS

FIG. 1 is a cross-sectional diagram of a MOS transistor according to first and second embodiments of the present invention;

FIG. 2 is a diagram showing the relationship between gate leak current and EOT according to the present invention;

FIG. 3 is a flowchart to form the MOS transistor according to the first embodiment of the present invention; and

FIG. 4 is a flowchart to form the MOS transistor according to the second embodiment of the present invention.

### DETAILED DESCRIPTION OF THE INVENTION

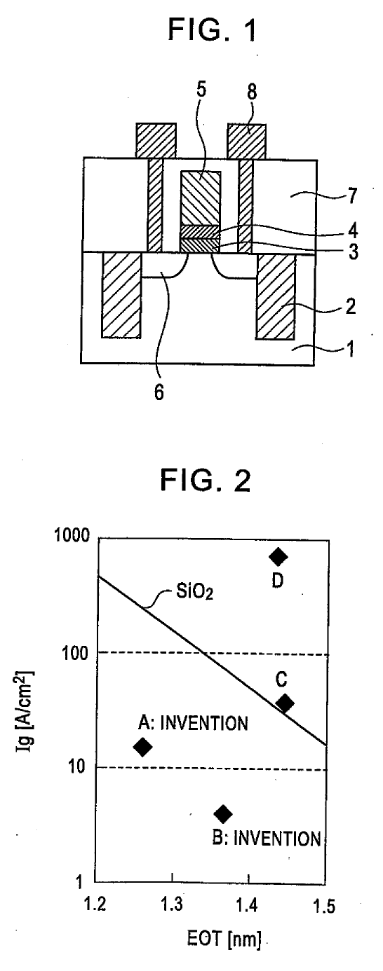

The embodiments of the present invention are described in detail with reference to FIG. 1 through FIG. 4.

### First Embodiment

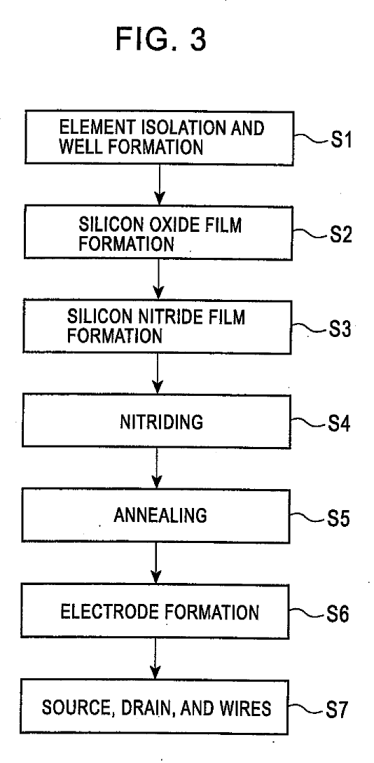

Referring to FIG. 1 and FIG. 3, the isolated elements 2 are formed on the semiconductor substrate 1 with a known method (STI in this embodiment) (Step S1 in FIG. 3). Then, wells and channels are formed with the ion implantation method (not shown in FIG. 1) (Step S1 in FIG. 3). STI stands for shallow trench isolation.

Next, the silicon oxide film 3 is formed to a thickness of between 0.5 nm and 1.5 nm over the entire surface (Step S2). The silicon oxide film is formed using the thermal oxidation method or plasma oxidation method or any other suitable method.

Next, the silicon nitride film 4 is formed to a thickness of between 0.2 nm and 1 nm using the LPCVD (Low Pressure Chemical Vapor Deposition) method (Step S3). Since formation of an extremely thin film is necessary in the LPCVD method, it is preferred that the ALD (Atomic Layer Deposition) method is used together with the LPCVD method.

Next, the silicon nitride film 4 is nitrided using the plasma nitriding method (Step S4). The silicon nitride film 4 is extremely thin, Thus, when nitriding is conducted with the high temperature thermal nitriding method, the nitrogen may be thermally diffused into the silicon oxide film 3, and even into the semiconductor substrate 1. In order to avoid this, use of the plasma nitriding method is preferred.

Annealing is conducted in an inert gas atmosphere at a temperature of between 900° C. and 1100° C. for between 1 and 100 seconds (Step S5).

The gate electrode 5 is formed by diffusing an impurity in polysilicon, and patterning (Step S6).

Next, using a known method, the source and drain 6 are formed using the ion implantation method, and the interlaminar film 7 and the wires 8 formed sequentially, thus forming a MOS transistor (Step S7).

FIG. 2 is a diagram illustrating the effects of the embodiment of the present invention. This diagram shows the relationship between gate leak current (Ig) and film thickness (EOT). Samples A and B have silicon oxide films formed to a thickness of 0.9 nm with the plasma oxidation method. The sample A has a silicon nitride film formed to a thickness of 0.25 nm with the ALD method, and the sample B has a silicon nitride film formed to a thickness of 0.5 nm with the ALD method.

The nitriding is then conducted on the samples A and B with the plasma nitriding method, followed by annealing at 1000° C. for 30 seconds in a nitrogen atmosphere. As reference, samples C and D are prepared. Each sample C, D has a silicon oxide film formed to a thickness of 0.9 nm, and a silicon nitride film formed to a thickness of 0.5 nm. The sample C is then annealed at 1000° C. for 30 seconds in a nitrogen atmosphere. The sample D is an example of simple formation of a silicon nitride film on the silicon oxide film. Ig is greater than SiO₂ in the sample D.

One reason is because it is an extremely thin film.

As understood from FIG. 2, Ig can be reduced by annealing (reduced from D to C). However, the present invention can achieve much greater improvement on the quality of the silicon nitride film (from C to B) by nitriding. The present invention can dramatically reduce Ig, far below SiO₂. This is thought to be due to the fact that nitriding is conducted at a self-governing rate, and thus the weak part of the silicon nitride film, for example, the part reduced in thickness, is nitrided and restored first. In general, when nitrogen enters a silicon oxide film of a thickness of about 1 nm or less, film thickness is increased. However, in the present invention, since film thickness is reduced from C to B, nitrogen is not diffused into the silicon oxide film upon nitriding. In other words, since nitrogen is not dispersed in the interface between the silicon oxide film and the substrate during nitriding, the device characteristics do not deteriorate.

As described above, a two-layer structure of the silicon oxide film 3 and the silicon nitride film 4 is made in the silicon oxynitride film by the method of the present embodiment. Therefore, nitrogen does not reach the interface of the gate insulation film and the silicon substrate 1, and quality of the silicon nitride film 4 is improved. Accordingly, it is possible to reduce Ig and also possible to prevent deterioration of the device characteristics.

### Second Embodiment

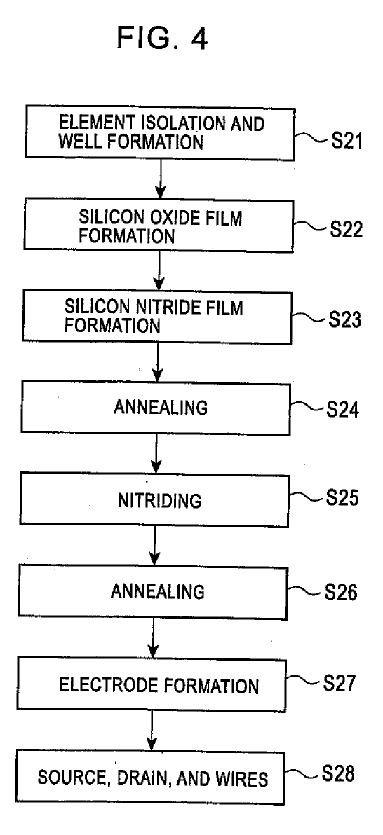

The second embodiment is described with reference to FIG. 1 and FIG. 4. FIG. 4 shows the flowchart to form the MOS transistor. The second embodiment is similar to the first embodiment so that only the differences are described below.

Steps S21 to S23 in FIG. 4 (second embodiment) are similar to steps Si to S3 in FIG. 3 (first embodiment).

After the silicon nitride film 4 is formed (Step S23), annealing is performed in an inert gas atmosphere at a temperature of between 900° C. and 1100° C. for between 1 and 100 seconds (Step S24). Nitriding is then performed (Step S25), and again the annealing is performed in an inert gas atmosphere at a temperature of between 900° C. and 1100° C. for between 1 and 100 seconds (Step S26).

Next, the gate electrode 5 is formed by diffusing an impurity in polysilicon, and patterning (Step S27).

Next, using a known method, the source and drain 6 are formed using the ion implantation method, and the interlaminar film 7 and the wires 8 formed sequentially (Step S28), thus forming a MOS transistor.

In the second embodiment, since annealing is conducted prior to nitriding, the interface between the silicon nitride film 4 and the silicon oxide film 3 is stabilized, and the density of the silicon nitride film 4 is increased Diffusion of nitrogen into the silicon oxide film 3 during nitriding is therefore further reduced, and diffusion of nitrogen in the interface between the gate insulation film and the silicon substrate 1 becomes increasingly difficult in the silicon oxynitride film. It is also possible to prevent deterioration of the device characteristics by improving the quality of the silicon nitride film 4.

In particular, when the gate insulation film is further reduced in thickness, and the silicon oxide film 3 and the silicon nitride film 4 become thinner, this method is effective in preventing defects such as pinholes and the like. The pinholes would cause diffusion of nitrogen.

This application is based on a Japanese Patent application No. 2004-294982 filed on Oct. 7, 2004 and the entire disclosure thereof is incorporated herein by reference.

What is claimed is:

1. A manufacturing method for a semiconductor device, comprising:
forming a silicon oxide film on a semiconductor substrate;
forming a silicon nitride film on the silicon oxide film;
nitriding the silicon nitride film;
a first heat treatment following said nitriding of the silicon nitride film; and
a second heat treatment between said forming of the silicon nitride film and said nitriding of the silicon nitride film,
wherein said nitriding is radical nitriding with nitrogen plasma that proceeds at a self-governing rate, and wherein a thickness of a laminated film including the silicon oxide film and the silicon nitride film is maintained during said nitriding.

2. The manufacturing method for a semiconductor device according to claim 1, wherein said forming of the silicon nitride film is performed with an ALD (Atomic Layer Deposition) method.

3. The manufacturing method for a semiconductor device according to claim 1, wherein the nitriding is radical nitriding with nitrogen plasma.

4. The manufacturing method for a semiconductor device according to claim 1, wherein the first heat treatment includes annealing and the second heat treatment also includes annealing.

5. The manufacturing method for a semiconductor device according to claim 4, wherein the annealing is conducted in an inert gas atmosphere.

6. The manufacturing method for a semiconductor device according to claim 1, wherein the silicon oxide film is formed by a thermal oxidation method or a plasma oxidation method.

7. The manufacturing method for a semiconductor device according to claim 1, wherein the silicon nitride film is formed by a low pressure chemical vapor deposition method.

8. The manufacturing method for a semiconductor device according to claim 1, wherein the silicon oxide film is formed to a thickness between 0.5 nm and 1.5 nm and the silicon nitride film is formed to a thickness between 0.2 nm and 1 nm.

9. The manufacturing method for a semiconductor device according to claim 5, wherein each of the first and second annealing is conducted at a temperature between 900 and 1100° C. for 1 to 100 seconds.
